(19) United States
(12) Patent Application Publication
(10) Pub. No.: US 2024/0302449 A1
(43) Pub. Date: Sep. 12, 2024

(54) BATTERY SENSING UNIT AND BATTERY BUSBAR MODULE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Shoto SHIGITA, Yokkaichi-shi, Mie (JP)

(21) Appl. No.: 18/259,143

(22) PCT Filed: Dec. 14, 2021
(86) PCT No.: PCT/JP2021/045933

§ 371 Date: Jun. 23, 2023

(30) Foreign Application Priority Data
Dec. 28, 2020 (JP) 2020-218496

(51) Int. Cl. G01R 31/396; G01R 31/3835

(52) U.S. Cl. CPC G01R 31/396; G01R 31/3835

(57) ABSTRACT

It is an object to provide a technology that can simplify wiring for a battery sensing unit. A battery sensing unit including a circuit board; a monitoring circuit that is mounted on the circuit board and is configured to monitor the state of the battery pack; and a first connector and a second connector that are mounted on the circuit board and are for connecting the monitoring circuit to an external device. The circuit board is provided spanning from a first end portion to a second end portion of the battery pack in an arrangement direction in which the plurality of battery cells are arranged, the first connector is provided at the first end portion and the second connector is provided at the second end portion, and the circuit board includes a conductive pattern that connects the first connector and the second connector to the monitoring circuit.

### CROSS-REFERENCE TO RELATED APPLICATIONS

This application is the U.S. national stage of PCT/JP2021/045933 filed on Dec. 14, 2021, which claims priority of Japanese Patent Application No. JP 2020-218496 filed on Dec. 28, 2020, the contents of which are incorporated herein.

### TECHNICAL FIELD

The present disclosure relates to a battery sensing unit and a battery busbar module.

### BACKGROUND

JP 2014-512660 discloses a sensing board for detecting the voltage and temperature of a battery cell. The sensing board is provided with one connector for connection to an external device. Wiring such as a wire harness that connects the sensing board to the external device is connected to this connector.

There is demand for the simplification of wiring that connects a sensing board and an external device to each other.

Thus, it is an object to provide a technology that can simplify wiring for a battery sensing unit.

### SUMMARY

A battery sensing unit of the present disclosure is a battery sensing unit that detects a state of a battery pack provided with a plurality of battery cells, including: a circuit board; a monitoring circuit that is mounted on the circuit board and is configured to monitor the state of the battery pack; and a first connector and a second connector that are mounted on the circuit board and are for connecting the monitoring circuit to an external device, wherein the circuit board is provided spanning from a first end portion to a second end portion of the battery pack in an arrangement direction in which the plurality of battery cells are arranged, the first connector is provided at the first end portion and the second connector is provided at the second end portion, and the circuit board includes a conductive pattern that connects the first connector and the second connector to the monitoring circuit.

### Advantageous Effects

With the present disclosure, wiring for a battery sensing unit can be simplified.

### BRIEF DESCRIPTION OF DRAWINGS

FIG. 1 is a perspective view showing a battery sensing unit and a battery busbar module provided with the same according to Embodiment 1.

FIG. 2 is a plan view showing the battery sensing unit and the battery busbar module provided with the same according to Embodiment 1.

FIG. 3 is a diagram showing a functional configuration of the battery sensing unit.

FIG. 4 is an exploded perspective view showing the battery sensing unit according to Embodiment 1.

FIG. 5 is a diagram showing an example of a battery system employing the battery sensing unit according to Embodiment 1.

FIG. 6 is a diagram showing an example of a battery system employing a battery sensing unit according to a comparative example.

FIG. 7 is an exploded perspective view of a battery sensing unit according to a variation.

### DETAILED DESCRIPTION OF PREFERRED EMBODIMENTS

First, embodiments of the present disclosure will be listed and described.

A battery sensing unit of the present disclosure is as follows.

(1) A battery sensing unit that detects a state of a battery pack provided with a plurality of battery cells, including: a circuit board; a monitoring circuit that is mounted on the circuit board and is configured to monitor the state of the battery pack; and a first connector and a second connector that are mounted on the circuit board and are for connecting the monitoring circuit to an external device, wherein the circuit board is provided spanning from a first end portion to a second end portion of the battery pack in an arrangement direction in which the plurality of battery cells are arranged, the first connector is provided at the first end portion and the second connector is provided at the second end portion, and the circuit board includes a conductive pattern that connects the first connector and the second connector to the monitoring circuit. By providing the first connector provided at the first end portion and the second connector provided at the second end portion, it is possible to suppress an increase in the length of wiring that connects battery sensing units to each other, regardless of the layout or the like of the battery packs. Thus, wiring for a battery sensing unit can be simplified.

(2) In the battery sensing unit of (1), the circuit board may include a first flexible printed circuit on which the first connector is mounted, and the first flexible printed circuit may include a first detection pattern that transmits first information regarding the state of the battery pack. Accordingly, wiring of the detection wires in the battery sensing unit is facilitated.

(3) In the battery sensing unit of (2), the first flexible printed circuit may include a first connector mounting portion where the first connector is mounted, and a first extended portion that extends in the arrangement direction from the first connector, and the first detection pattern may include a first voltage detection pattern that is provided on the first extended portion and transmits information regarding a voltage of the battery cells. Accordingly, the voltage detection pattern can extend to the electrodes of the battery cells via the extended portion, and the voltage detection pattern and the electrodes can be easily connected to each other. There is no need to use a coated wire as the wiring connected to the electrodes to detect the voltages.

(4) In the battery sensing unit of (3), the circuit board may include a second flexible printed circuit on which the second connector is mounted, and the second flexible printed circuit may include a second detection pattern that transmits second information regarding the state of the battery pack. Accordingly, by dividing the flexible printed circuit, the area in which the flexible printed circuit is provided can be reduced.

(5) In the sensing unit of (4), the second flexible printed circuit may include a second connector mounting portion on which the second connector is mounted, and a second extended portion that extends in the arrangement direction from the second connector mounting portion, the second detection pattern may be provided on the second extended portion and include a second voltage detection pattern that transmits information regarding a voltage of the battery cells, and the first voltage pattern and the second voltage pattern may transmit voltage information regarding different battery cells. This makes it easier to optimize the route of the voltage detection pattern.

(6) In the battery sensing unit of (5), two of the first extended portion may be provided on the first flexible printed circuit so as to be separated from each other in a direction that intersects the arrangement direction, two of the second extended portion may be provided on the second flexible printed circuit so as to be separated from each other in a direction that intersects the arrangement direction, the first voltage detection pattern provided on the first extended portions may be connected to the battery cells on the first end portion side of the plurality of battery cells, and the second voltage detection pattern provided on the second extended portions may be connected to the battery cells on the second end portion side of the plurality of battery cells. Thus, there is no voltage detection pattern that extends from one of the first end portion and the second end portion to the other thereof, and an increase in the width of the extension portions can be suppressed.

(7) In the battery sensing unit of (3), the first flexible printed circuit may include a second connector mounting portion on which the second connector is mounted, and the first connector mounting portion and the second connector mounting portion may be joined to each other via the first extended portion. Thus, the first connector and the second connector are provided on one flexible printed circuit.

(8) In the battery sensing unit of any one of (2) to (7), the circuit board may include a rigid board on which the monitoring circuit is mounted. Accordingly, it is possible to suppress an increase in the manufacturing cost of the battery sensing unit.

(9) The battery sensing unit of (8) may further include a third connector that connects the rigid board and the first flexible printed circuit to each other, wherein the third connector is provided at an end portion on the first end portion side of the rigid board in the arrangement direction. Thus, the third connector is provided at a position where space is comparatively available.

(10) Also, a battery busbar module according to the present disclosure including: the battery sensing unit according to any one of (1) to (9); a plurality of busbars that connect the plurality of battery cells in series; and a case that houses the plurality of busbars and the battery sensing unit. Thus, the battery sensing unit and the busbars are held in a predetermined positional relationship by the case.

Specific examples of a battery sensing unit of the present disclosure are described below with reference to the drawings. Note that the present disclosure is not limited to these examples, but is indicated by the claims, and all changes that come within the meaning and range of equivalency of the claims are intended to be embraced therein.

### Embodiment 1

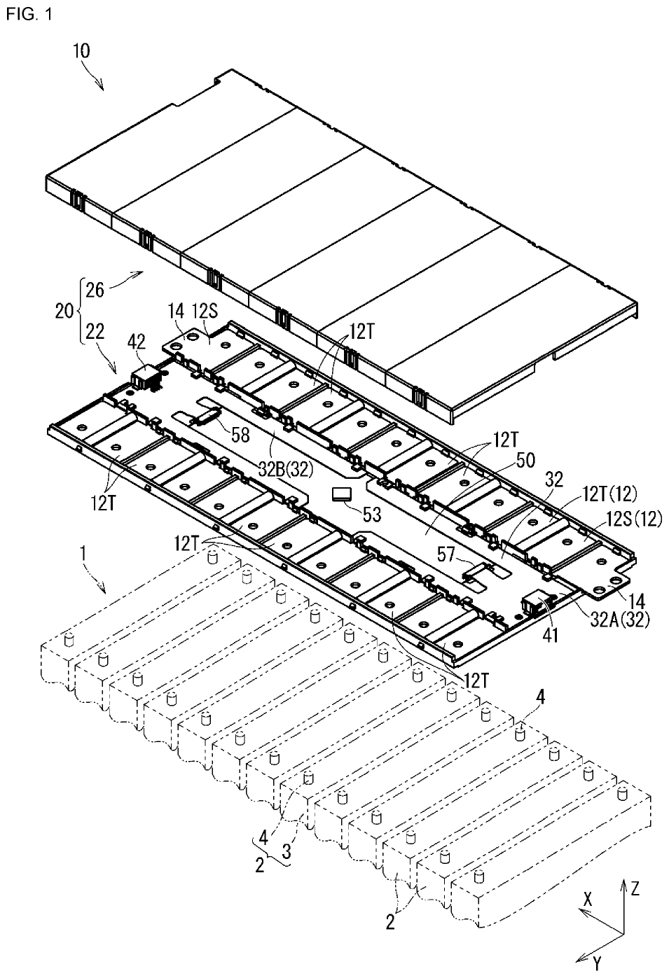

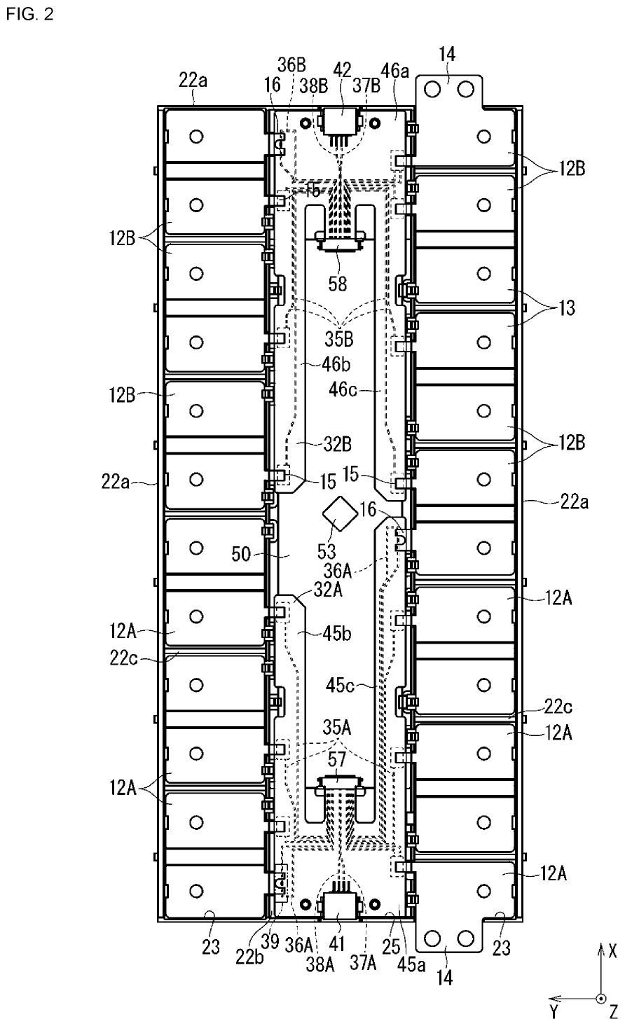

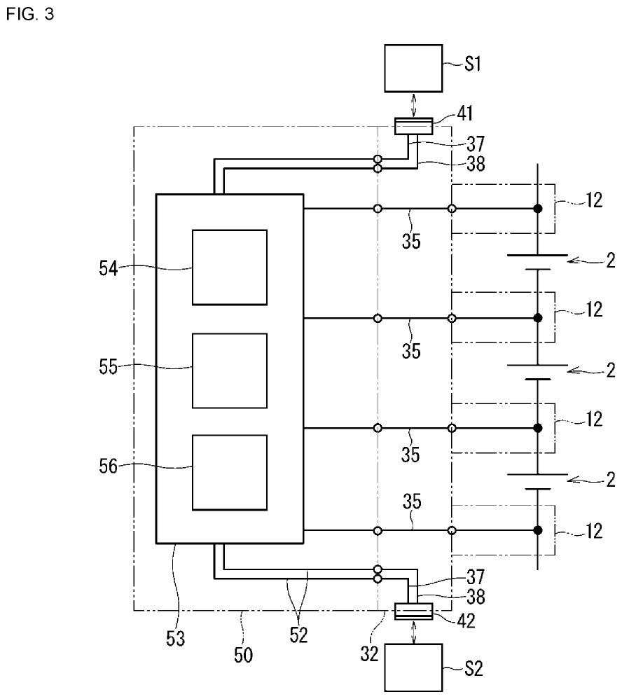

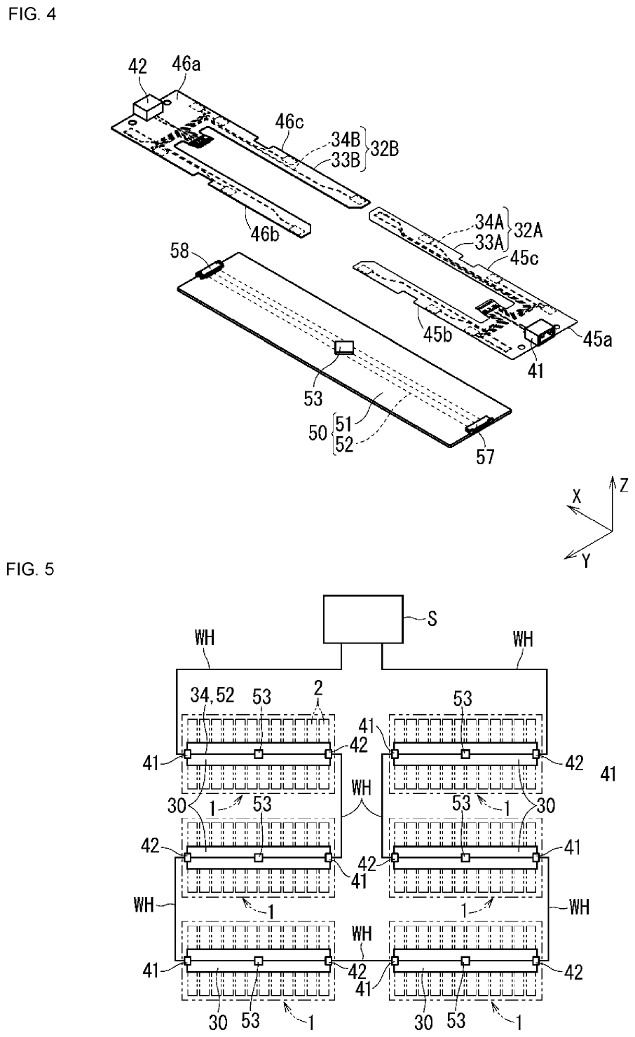

The following is a description of a battery sensing unit according to Embodiment 1. FIG. 1 is a perspective view of a battery sensing unit 30 and a battery busbar module 10 provided with the same according to Embodiment 1. FIG. 2 is a plan view of the battery sensing unit 30 and the battery busbar module 10 provided with the same according to Embodiment 1. FIG. 3 is a diagram showing a functional configuration of the battery sensing unit 30. FIG. 4 is an exploded perspective view showing the battery sensing unit 30 according to Embodiment 1.

### Battery

First, an example of a battery will be described. A battery is used as a power source for driving a vehicle such as an electric car or hybrid car. The battery includes a battery pack 1. The battery pack 1 includes a plurality (twelve in the example shown in FIG. 1) of battery cells 2. In the example shown in FIG. 1, the battery cells 2 are arranged in one row in one battery pack 1. In the present disclosure, the arrangement direction in which the battery cells 2 are arranged is the X direction, and two directions orthogonal to the X direction are the Y direction and the Z direction. One side in the Z direction may be referred to as the upper side, and the other side may be referred to as the lower side. Naturally, more than one row of battery cells 2 may be arranged in one battery pack 1.

Each battery cell 2 includes a cell body 3 and electrode terminals 4. Electricity generating elements are contained in the cell body 3. Each battery cell 2 is provided with two electrode terminals 4, namely a positive electrode and a negative electrode, as the electrode terminals 4. In the example shown in FIG. 1, one battery cell 2 is provided with the two electrode terminals 4 that protrude in the Z direction from the cell body 3 and are separated from each other in the Y direction. The battery cells 2 are arranged such that the orientations of the positive and negative electrodes are reversed between two adjacent battery cells 2. In one battery pack 1, the battery cells 2 are connected in series.

For example, a battery module provided with a plurality of battery packs 1 is used as a vehicle battery. Battery busbar modules 10 are respectively attached to the battery packs 1.

### Battery Busbar Module

The battery busbar module 10 is provided with a plurality of busbars 12, a case 20, and a battery sensing unit 30. The busbars 12 connect the battery cells 2 in series. The battery sensing unit 30 detects the state of the battery pack 1. The case 20 houses the busbars 12 and the battery sensing unit 30. The busbars 12 and the battery sensing unit 30 are held in a predetermined positional relationship due to being housed in the case 20. The battery busbar module 10 is attached to the battery pack 1 from the Z direction.

### Busbar

Each busbar 12 has a cell connection portion 13. The cell connection portion 13 is a portion that is connected to a battery cell 2. The cell connection portion 13 can be appropriately set according to the shape or the like of the electrodes of the battery cell 2. Here, the cell connection portion 13 has a flat plate shape. The cell connection portion 13 is provided with a through-hole. By inserting an electrode terminal 4 into the through-hole and screw-locking the portion of the electrode terminal 4 protruding from the through-hole, the cell connection portion 13 and the battery cell 2 are connected to each other.

Busbars 12S that have only one cell connection portion 13 and busbars 12T that have two cell connection portions 13 are provided as the busbars 12. Two busbars 12S are provided. The two busbars 12S are correspondingly connected to electrode terminals 4 at two ends of the battery pack 1. Each busbar 12S is provided with an external conductor connection portion 14. The battery pack 1 is connected to an adjacent battery pack 1 or an external load of a power supply target or the like via external conductors connected to the external conductor connection portions 14. The two busbars 12S are the positive and negative terminals of the battery pack 1 when the battery pack 1 is viewed as a single battery. The busbars 12T connect two adjacent battery cells 2 to each other. One of the two cell connection portions 13 of the busbar 12T is connected to an electrode terminal 4 of one of the two adjacent battery cells 2. The other of the two cell connection portions 13 of the busbar 12T is connected to an electrode terminal 4 of the other of the two adjacent battery cells 2. Below, the busbars 12S and 12T may be referred to as the busbars 12 when they do not need to be distinguished from one another.

Each busbar 12 is provided with a voltage detection wire connection portion 15. The voltage detection wire connection portion 15 is provided so as to protrude from a portion of the outer edge of the cell connection portion 13. Here, the voltage detection wire connection portion 15 protrudes in the Y direction from a portion of the outer edge of the cell connection portion 13.

At least one of the plurality of busbars 12 is provided with a temperature sensor holding portion 16. The temperature sensor holding portion 16 is provided so as to protrude from a portion of the outer edge of the cell connection portion 13. Here, the temperature sensor holding portion 16 protrudes in the Y direction from a portion of the outer edge of the cell connection portion 13. Three busbars 12T are provided with the temperature sensor holding portion 16. The three busbars 12T are disposed divided between positions at two end portions in the X direction and a position at an intermediate portion that is near the center. In each busbar 12T, the voltage detection wire connection portion 15 protrudes from one of the two cell connection portions 13, and the temperature sensor holding portion 16 protrudes from the other cell connection portion 13.

### Case

The case 20 includes a case body 22 and a cover 26.

In a plan view, the case body 22 has a rectangular shape that is comparable in size to the battery pack 1. The case body 22 includes busbar housing portions 23 and a board housing portion 25. In this example, the two end portions of the case body 22 in the Y direction are the busbar housing portions 23, and the space between these two busbar housing portions 23 is the board housing portion 25. The busbar housing portions 23 each have a frame shape in which the busbars 12 can be individually housed. The board housing portion 25 has a frame shape in which a circuit board can be housed. The busbars 12 are partitioned from each other, and the circuit board and the busbars 12 are partitioned from each other. More specifically, the case body 22 includes an outer frame portion 22a and an inner frame portion. In a plan view, the outer frame portion 22a demarcates the outer edge of the case body 22. The inner frame portion is provided inside the outer frame portion 22a. The inner frame portion includes vertical frame portions 22b and horizontal frame portions 22c. The vertical frame portions 22b extend in the X direction at positions of an intermediate portion in the Y direction. Two vertical frame portions 22b are provided. The horizontal frame portions 22c extend in the Y direction and join the outer frame portion 22a and the vertical frame portions 22b to each other. The horizontal frame portions 22c are provided between adjacent busbars 12. The individual housing spaces of the busbars 12 are demarcated by the outer frame portion 22a, the vertical frame portions 22b, and the horizontal frame portions 22c. The outer frame portion 22a and the two vertical frame portions 22b demarcate the housing space of the circuit board.

As shown in FIG. 5, the busbar housing portions 23 support the bottom surfaces of the busbars 12 so that the portions of the cell connection portions 13 where the through-holes are provided can be exposed. Support pieces of the busbar housing portions 23 support the lower surfaces of the outer edge portions of the cell connection portions 13 of the busbars 12. The busbar housing portions 23 may have busbar holding pieces that sandwich and hold the busbars 12 together with the support pieces. The busbar holding pieces can be provided on the outer frame portion 22a, the vertical frame portions 22b, or the like. The cell connection portions 13 and the temperature sensor holding portions 16 of the busbars 12 protrude toward the board housing portion 25. The vertical frame portions 22b are provided with openings through which the cell connection portions 13 and the temperature sensor holding portions 16 extend.

The board housing portion 25 has a board support portion that supports the lower surface of the board. The board support portion is provided in a region surrounded by the outer frame portion 22a and the vertical frame portions 22b. The board housing portion 25 may have a board holding piece that sandwiches and holds the circuit board together with the board support portion. The board holding piece can be provided on the vertical frame portions 22b or the like.

The cover 26 includes a cover body and a peripheral wall portion. The cover body covers the busbars 12 and the circuit board housed in the case body 22. The peripheral wall portion protrudes from an outer edge of the cover body. The peripheral wall portion surrounds the case body 22 and the outer frame portion 22a. The case body 22 and the cover 26 are detachably attached to each other by locking protrusions formed on one of the case body 22 and the cover 26 with locking recessions formed on the other. In this example, the locking protrusions are formed on the case body 22 and the locking recessions are formed on the cover 26.

In a state where the cover 26 is attached to the case body 22, the external conductor connection portions 14 protrude outward from the case 20. Also, a first connector 41 and a second connector 42 (described below) are exposed so as to be connectable to a partner connector. The case 20 is provided with openings through which the external conductor connection portions 14 protrude, and openings for exposing the first connector 41 and the second connector 42. These openings are formed in the outer frame portion 22a and the peripheral wall portion.

### Battery Sensing Unit

The battery sensing unit 30 is provided with the circuit board and a voltage detection unit. The circuit board is provided extending in the X direction from a first end portion to a second end portion of the battery pack 1. The voltage detection unit can detect the voltage value of the battery. The battery sensing unit 30 is also provided with a temperature detection unit. The temperature detection unit can detect the temperature of the battery.

The circuit board includes a flexible printed circuit (FPC) 32 and a rigid printed circuit (RPC) 50.

The FPC 32 includes an insulating layer 33 and conductive patterns 34. The insulating layer 33 is formed into a film shape using a resin that has insulating properties, such as polyimide. The insulating layer 33 includes a base layer. The conductive patterns 34 are conductors made of copper or the like and is printed onto the base layer. The insulating layer 33 may include a cover layer. The cover layer may be provided so as to cover the conductive patterns 34 without covering a connection portion thereof. Temperature sensors 39, the first connector 41, and the second connector 42 are mounted on the FPC 32.

Voltage detection patterns 35, temperature detection patterns 36, power supply patterns 37, and signal patterns 38 are provided as the conductive patterns 34. One end portion of each of the voltage detection patterns 35, the temperature detection patterns 36, the power supply patterns 37, and the signal patterns 38 is connected to the RPC 50.

The voltage detection patterns 35 form a portion of the voltage detection unit. The number of voltage detection patterns 35 matches the number of busbars 12. The voltage detection patterns 35 are connected to the voltage detection wire connection portions 15 of the busbars 12, respectively. The voltage detection patterns 35 individually transmit a voltage signal that corresponds to the voltage of the busbar 12 connected thereto. Each voltage detection pattern 35 is provided with a cell connection land. The cell connection land is connected to the voltage detection wire connection portion 15 of the busbar 12. The mode of connection between the cell connection land and the voltage detection wire connection portion 15 is not particularly limited, and soldering or the like may be employed. The cell connection land and the voltage detection wire connection portion 15 are connected to each other with the voltage detection wire connection portion 15 being located above the cell connection land.

The temperature detection patterns 36 form a portion of the temperature detection unit. The number of temperature detection patterns 36 corresponds to the number of temperature sensors 39. Here, three temperature sensors 39 are provided, and more than one temperature detection pattern 36 is connected to each temperature sensor 39. The temperature sensors 39 are held by the temperature sensor holding portions 16 provided on some of the busbars 12.

The power supply patterns 37 are patterns for supplying power for the battery sensing unit 30. The signal patterns 38 transmit signals between the battery sensing unit 30 and the external devices S1 and S2. In the FPC 32, a power supply pattern 37 and a signal pattern 38 join the first connector 41 and a third connector 57 to each other. Also, a power supply pattern 37 and a signal pattern 38 join the second connector 42 and a fourth connector 58 to each other. Power is supplied from the external device S1 connected to this battery sensing unit to a power distribution unit such as a monitoring IC 53 or a power supply IC, via the first connector 41, the power supply pattern 37, and the third connector 57. For example, the temperature sensors 39 can detect current and temperature using power supplied by the power supply pattern 37. Also, power supplied from the external device S1 is supplied to the external device S2 connected to this battery sensing unit, via the fourth connector 58, the power supply pattern 37, and the second connector 42. The monitoring IC 53 and the external devices S1 and S2 transmit signals via the signal patterns 38.

The temperature sensors 39 form a portion of the temperature detection unit. Here, a thermistor is used as the temperature sensor 39. Two lead lines of the thermistor are connected to the two temperature detection patterns 36. The two voltages applied to the two temperature detection patterns 36 are signals that correspond to the temperature of the temperature sensor 39 (signals than can specify the temperature of the temperature sensor 39). For example, the potential difference between two temperature detection patterns 36 can be used to specify the temperature at the position where the temperature sensor 39 is located. Naturally, a semi-conductor sensor or the like may be used as the temperature sensor 39 in place of the temperature sensor 39 constituted by a thermistor.

The first connector 41 is a member for electrically connecting the battery sensing unit 30 and the external device S1 to each other. The second connector 42 is a member for electrically connecting the battery sensing unit 30 and the external device S2 to each other. The first connector 41 and the second connector 42 each include a connector housing and a connector terminal. One end portion of the connector terminal is connected to the conductive patterns 34, and the other end portion of the connector terminal is housed in the connector housing so as to be connectable to a partner terminal or the like. For example, the first connector 41 and the second connector 42 are respectively connected to connectors provided at end portions of wire harnesses WH (see FIG. 5). The battery sensing unit 30 is electrically connected to the external devices S1 and S2 via the first connector 41, the second connector 42, and the wire harnesses WH. The external devices S1 and S2 are an external controller S (see FIG. 5) or an adjacent battery sensing unit 30. The external controller S may transmit signals for executing processing for detecting voltage, current, temperature, and the like to the battery sensing unit 30. The external controller S may control another device using a voltage value, a current value, temperature, or the like obtained based on a signal from the battery sensing unit 30.

In this example, a first FPC 32A and a second FPC 32B are provided as the FPC 32. The first FPC 32A and the second FPC 32B have a U shape in a plan view. The first FPC 32A and the second FPC 32B are disposed such that opening portions thereof oppose each other. The RPC 50 is exposed at the portion surrounded by the first FPC 32A and the second FPC 32B.

Specifically, the first FPC 32A includes a first portion 45a and first extended portions 45b and 45c. The first portion 45a is disposed on the outer side of the RPC 50 in the X direction, on the first end portion side. The first extended portions 45b and 45c are portions that extend in the X direction from the first portion 45a on two end sides of the first portion 45a in the Y direction. The first connector 41 is mounted on the first portion 45a. The first portion 45a includes a first connector mounting portion. Also, the portion where the first FPC 32A is connected to the RPC 50 is provided on the first portion 45a. The portion where the first FPC 32A is connected to the RPC 50 extends parallel to the first extended portions 45b and 45c, between the first extension portions 45b and 45c.

Also, the second FPC 32B includes a second portion 46a and second extended portions 46b and 46c. The second portion 46a is disposed on the outer side of the RPC 50 along the X direction, on the second end portion side. The second extended portions 46b and 46c are portions that extend in the X direction from the first portion 45a, on two end sides of the second portion 46a in the Y direction. The second connector 42 is mounted on the second portion 46a. The second portion 46a includes a second connector mounting portion. Also, the portion where the second FPC 32B is connected to the RPC 50 is provided on the second portion 46a. The portion where the second FPC 32B is connected to the RPC 50 extends parallel to the second extended portions 46b and 46c, between the second extension portions 46b and 46c.

The portion surrounded by the first portion 45a, the second portion 46a, the first extended portions 45b and 45c, and the second extended portions 46b and 46c is an opening through which the RPC 50 is exposed. The first portion 45a, the second portion 46a, the first extended portions 45b and 45c, and the second extended portions 46b and 46c are housed in the board housing portion 25.

The voltage detection patterns 35, the temperature detection patterns 36, the power supply patterns 37, and the signal patterns 38 are provided on the first FPC 32A and the second FPC 32B. Below, the voltage detection patterns 35, the temperature detection patterns 36, the power supply pattern 37, and the signal pattern 38 provided on the first FPC 32A may be described with the symbol A. Similarly, the voltage detection patterns 35, the temperature detection patterns 36, the power supply pattern 37, and the signal pattern 38 provided on the second FPC 32B may be described with the symbol B.

The plurality of voltage detection patterns 35 and temperature detection patterns 36 extend to the detection-target battery cells 2 via the first portion 45a, the first extended portions 45b and 45c, the second portion 46a, and the second extended portions 46b and 46c. Signals from battery cells 2 located on one side of the intermediate portion of the battery cells 2 in the X direction are input to the RPC 50 from the first portion 45a. Signals from battery cells 2 located on the other side of the intermediate portion of the battery cells 2 in the X direction are input to the RPC 50 from the second portion 46a.

Specifically, voltage information regarding busbars 12A on the one side of the intermediate portion of the busbars 12 in the X direction is transmitted to the RPC 50 via the first voltage detection patterns 35A. Voltage information regarding busbars 12B on the other side of the intermediate portion of the busbars 12 in the X direction is transmitted to the RPC 50 via the second voltage detection patterns 35B. Also, temperature information regarding the busbar 12A at the first end portion of the busbars 12 in the X direction and temperature information regarding the busbar 12B located at the intermediate portion is transmitted to the RPC 50 via the temperature detection patterns 36A. Also, temperature information regarding the busbar 12B at the second end portion of the busbars 12 in the X direction is transmitted to the RPC 50 via the temperature detection pattern 36B.

A power supply pattern 37A and a signal pattern 38A extend from the connection portion between the first FPC 32A and the RPC 50 to the first connector 41, via the first portion 45a. A power supply pattern 38B and a signal pattern 38B extend from the connection portion between the second FPC 32B and the RPC 50 to the second connector 42, via the second portion 46a.

The RPC 50 includes an insulating layer 51 and a conductive pattern 52. The insulating layer 51 includes a base layer constituted by a glass epoxy substrate or the like. The conductive pattern 52 is a conductor made of copper or the like and is printed onto the base layer. The insulating layer 51 may include a cover layer. The cover layer may be provided so as to cover the conductive pattern 52 without covering a connection portion thereof. A monitoring IC 53, the third connector 57, and the fourth connector 58 are mounted on the RPC 50.

The monitoring IC (monitoring circuit) 53 is constituted by a micro-computer including a CPU, a ROM, a RAM, and the like or another hardware circuit. The monitoring IC 53 is provided with a plurality of input terminals. The voltage detection patterns 35, the temperature detection patterns 36, the power supply patterns 37, and the signal patterns 38 are correspondingly connected to the input terminals via the conductive pattern 52. The monitoring IC 53 is formed by integrating a detection unit 54, a communication unit 55, a control unit 56, and the like.

The detection unit 54 can detect the terminal voltage of each battery cell 2 based on voltage signals received via the voltage detection patterns 35. Also, the detection unit 54 can detect the battery temperature based on temperature signals received via the temperature detection patterns 36.

The communication unit 55 receives instructions regarding the battery sensing unit 30 from the external controller S. Also, for example, the communication unit 55 transmits signals regarding the battery state detected by the battery sensing unit 30 to the external controller S. In this example, the communication unit 55 and the external controller S are wire-connected to each other via the first connector 41 and the second connector 42. The connection relation between the communication unit 55 and the external controller S is described below.

The control unit 56 performs control that corresponds to instructions received from the communication unit 55, for example. The control unit has the function of, when, for example, the communication unit 55 receives a predetermined notification instruction transmitted from the external controller S, performing response processing for ascertaining battery voltage and temperature based on signals from the voltage detection unit and the temperature detection unit, and transmitting the information regarding the battery voltage and temperature to another battery sensing unit 30 or the external controller S.

Note that, in the battery sensing unit 30, the detection unit 54, the communication unit 55, and the control unit 56 do not necessarily need to be integrated, and may be separately mounted on the circuit board. Also, the battery sensing unit 30 may have an AD conversion circuit that converts received analogue signals into digital signals. The AD conversion circuit may be integrated into the monitoring IC 53 or mounted on the circuit board separately from the monitoring IC 53.

The third connector 57 is used for connection to the first FPC 32A. The first FPC 32A and the RPC 50 are connected to each other via the third connector 57. The third connector 57 includes a connector housing and a connector terminal. The first FPC 32A and the RPC 50 may be connected to each other without using the third connector 57. The first FPC 32A and the RPC 50 may be integrated as a flex-rigid board.

The fourth connector 58 is used for connection to the second FPC 32B. The second FPC 32B and the RPC 50 are connected to each other via the fourth connector 58. The fourth connector 58 includes a connector housing and a connector terminal. The second FPC 32B and the RPC 50 may be connected to each other without using the fourth connector 58. The second FPC 32B and the RPC 50 may be integrated as a flex-rigid board.

In addition, elements and the like required for a voltage detection circuit, a temperature detection circuit, a power distribution circuit, a communication circuit, and the like can be mounted on the FPC 32 and the RPC 50 as needed. For example, a resistor, a Zener diode, and the like may be used for a voltage detection circuit, and these elements may be mounted on the FPC 32 and the RPC 50.

### Battery System

FIG. 5 is a diagram showing an example of a battery system employing the battery sensing unit 30 according to Embodiment 1.

There are cases where a battery system in a vehicle or the like is constituted by a plurality of battery packs 1 that each include a plurality of battery cells 2, as shown in FIG. 5, for example. A battery sensing unit 30 is attached to each battery pack 1. The battery sensing units 30 are connected to an external controller S that unifies the battery systems. The external controller S is an electronic control unit (ECU), for example. The battery sensing units 30 and the external controller S are connected to each other by wire harnesses or the like. In the example shown in FIG. 5, the battery sensing units 30 and the external controller S are wire-connected to each other in a daisy chain configuration. In FIG. 5, the external controller S and six battery sensing units 30 are connected to each other in a daisy chain configuration.

Here, the battery packs 1 as well as the busbars 12S are directly connected to each other or indirectly connected to each other using another connection member. A large current flows through the connection portion between busbars 12S. On the other hand, a current as large as the current flowing through a connection portion between busbars 12S does not flow through the connection portion between battery sensing units 30 or the connection portion between a battery sensing unit 30 and the external controller S. Thus, it is of greater priority to reduce the wiring at the connection portions of the busbars 12S than at the connection portion between battery sensing units 30 or a connection portion between a battery sensing unit 30 and the external controller S. Thus, the layout of the battery packs 1 (the orientation and arrangement of the battery packs 1) is determined to maximally reduce the wiring at the connection portions of the busbars 12S. Depending on the layout of the battery packs 1, there is a concern that connection portions between the battery sensing units 30 and the connection portion between the battery sensing unit 30 and the external controller S will be long.

In this case as well, when the battery sensing unit 30 of the present disclosure is used, the first connector 41 and the second connector 42 are correspondingly provided at the first end portion and the second end portion of the battery sensing unit 30, and thus a reduction in the wiring of the wire harness WH for connection battery sensing units 30 to each other and the wire harness WH for connecting the battery sensing unit 30 to the external controller S can be achieved, as shown in FIG. 5.

### COMPARATIVE EXAMPLE

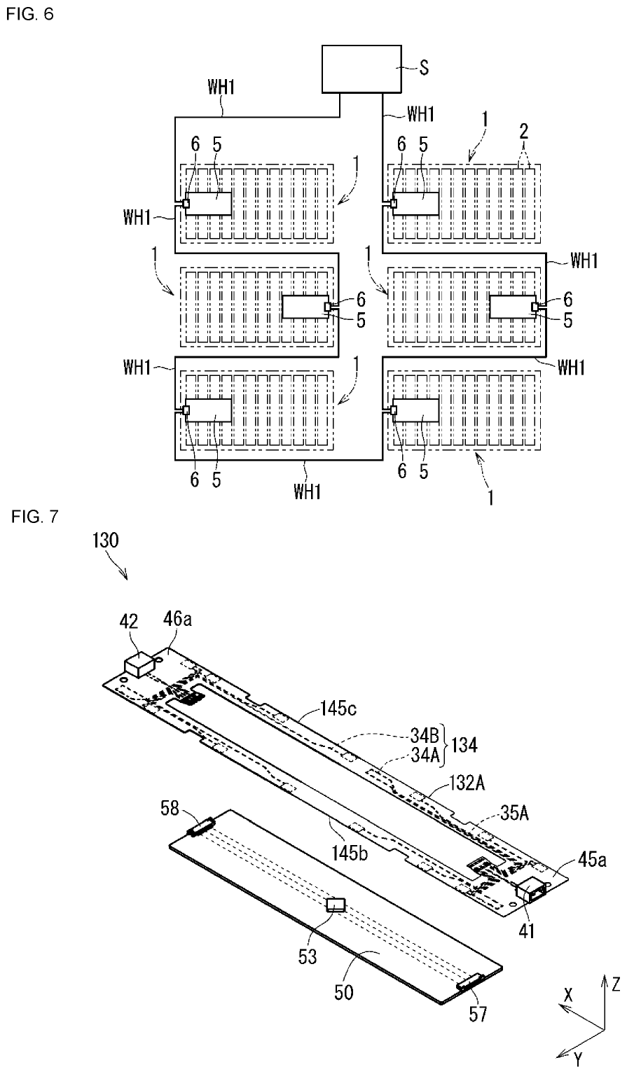

FIG. 6 is a diagram showing an example of a battery system employing a battery sensing unit 5 according to a comparative example.

In the example shown in FIG. 6, the battery sensing unit 5 is only provided with one connector 6 for external communication. Thus, depending on the layout and the like of the battery packs 1, there is a concern that a wire harness WH1 for connecting battery sensing units 5 to each other and a wire harness WH1 for connecting a battery sensing unit 5 and an external controller S to each other will be unnecessarily long, as shown in FIG. 6.

Effects, Etc. Of Embodiment 1

With the battery sensing unit 30 and the battery busbar module 10 including the same configured as described above, by providing the first connector 41 at the first end portion in the X direction and the second connector 42 at the second end portion, it is possible to suppress an increase in the length of the wire harnesses WH that connect the battery sensing units 30 to the external devices S1 and S2, regardless of the layout or the like of the battery packs 1. Thus, the wire harness WH for the battery sensing unit 30 can be simplified.

Also, the circuit board includes the first FPC 32A provided with a first detection pattern. Thus, wiring of a detection wire in the battery sensing unit 30 is facilitated.

Also, the first detection pattern is provided on the first extended portions 45b and 45c and includes the first voltage detection patterns 35A that transmit information regarding the voltages of the battery cells 2. Accordingly, the voltage detection patterns 35 can be extended to the electrodes of the battery cells 2 via the first extended portions 45b and 45c, and the voltage detection patterns 35 and the electrodes can be easily connected to each other. Also, there is no need to use a coated wire as the wiring connected to the electrodes to detect the voltage.

Also, the first FPC 32A and the second FPC 32B are provided. Thus, by dividing the FPC 32, the area in which the FPC 32 is provided can be reduced.

Also, the first voltage detection patterns 35A and the second voltage detection patterns 35B transmit voltage information regarding different battery cells 2. This makes it easier to optimize the route of the voltage detection patterns 35.

Also, the first voltage detection patterns 35A provided on the two first extended portions 45b and 45c are connected to the battery cells 2 on the first end portion side of the battery cells 2, and the second voltage detection patterns 35B provided on the two second extended portions 46b and 46c are connected to the battery cells 2 on the second end portion side of the battery cells 2. Thus, there is no voltage detection pattern that extends from one of the first end portion and the second end portion to the other, and an increase in the width of the extension portions can be suppressed.

Also, the circuit board includes the RPC 50 on which the monitoring IC 53 is mounted. Thus, an increase in the manufacturing cost of the battery sensing unit 30 can be suppressed.

Also, the third connector 57 is provided at the end portion on the first end portion side in the X direction of the RPC. Thus, the third connector 57 is provided at a position where space is comparatively available.

Also, with the battery busbar module 10, the battery sensing unit 30 and the busbars 12 are held in a predetermined positional relationship by the case 20.

### Variations

FIG. 7 is an exploded view showing a battery sensing unit 130 according to a variation.

The battery sensing unit 130 differs from the battery sensing unit 30 in that only one first FPC 132A is provided. The first FPC 132A has a shape where the first FPC 32A and the second FPC 32B are joined to each other. In the first FPC 132A, first extended portions 145b and 145c extend in the X direction from the first portion 45a. These first extended portions 145b and 145c extend to a second portion 46a where they can be deemed as being joined to the second portion 46a. A conductive pattern 134 of the first FPC 132A includes conductive patterns 34A of the first FPC 32A and the conductive patterns 34B of the second FPC 32B. With this battery sensing unit 130, the first connector 41 and the second connector 42 are provided on the one first FPC 132A.

Additionally, the first FPC 32A and the second FPC 32B were described as having a U shape in a plan view, but this is not an essential configuration. For example, the first FPC and the second FPC may have an L shape in a plan view. In this case, the voltage detection patterns for the busbars 12 on one end side in the Y direction are provided on the first FPC, and voltage detection patterns for the busbars on the other end side in the Y direction or provided on the second FPC.

Also, the voltage detection patterns were described as being provided divided between the first FPC and the second FPC. But this is not an essential configuration. A configuration may be employed where the voltage detection patterns are only provided on the first FPC and not on the second FPC. In this case, the second FPC does not need to be provided with second extended portions. Also, coated wires or the like may be used as the voltage detection wires in place of the voltage detection patterns.

Also, the first connector 41 and the second connector 42 were described as being mounted on an FPC, but this is not an essential configuration. One or both of the first connector 41 and the second connector 42 may be mounted on the RPC 50. For example, the first connector 41 may be mounted on the first FPC, and the second connector 42 may be mounted on the RPC. In this case, the first FPC may have a U shape, and the two first extended portions of the first FPC may be provided extending in the X direction from the first end portion to the second end portion.

Note that the configurations described in the aforementioned embodiments and variations can be combined as necessary, provided no contradiction arises.

1. A battery sensing unit that detects a state of a battery pack provided with a plurality of battery cells, comprising:
a circuit board;
a monitoring circuit that is mounted on the circuit board and is configured to monitor the state of the battery pack; and
a first connector and a second connector that are mounted on the circuit board and are for connecting the monitoring circuit to an external device,
wherein the circuit board is provided spanning from a first end portion to a second end portion of the battery pack in an arrangement direction in which the plurality of battery cells are arranged,
the first connector is provided at the first end portion and the second connector is provided at the second end portion, and
the circuit board includes a conductive pattern that connects the first connector and the second connector to the monitoring circuit.

2. The battery sensing unit according to claim 1,
wherein the circuit board includes a first flexible printed circuit on which the first connector is mounted, and
the first flexible printed circuit includes a first detection pattern that transmits first information regarding the state of the battery pack.

3. The battery sensing unit according to claim 2,
wherein the first flexible printed circuit includes a first connector mounting portion where the first connector is mounted, and a first extended portion that extends in the arrangement direction from the first connector, and
the first detection pattern includes a first voltage detection pattern that is provided on the first extended portion and transmits information regarding a voltage of the battery cells.

4. The battery sensing unit according to claim 3,
wherein the circuit board includes a second flexible printed circuit on which the second connector is mounted, and
the second flexible printed circuit includes a second detection pattern that transmits second information regarding the state of the battery pack.

5. The battery sensing unit according to claim 4,
wherein the second flexible printed circuit includes a second connector mounting portion on which the second connector is mounted, and a second extended portion that extends in the arrangement direction from the second connector mounting portion,
the second detection pattern is provided on the second extended portion and includes a second voltage detection pattern that transmits information regarding a voltage of the battery cells, and
the first voltage pattern and the second voltage pattern transmit voltage information regarding different battery cells.

6. The battery sensing unit according to claim 5,
wherein two of the first extended portion are provided on the first flexible printed circuit so as to be separated from each other in a direction that intersects the arrangement direction,
two of the second extended portion are provided on the second flexible printed circuit so as to be separated from each other in a direction that intersects the arrangement direction,
the first voltage detection pattern provided on the first extended portions is connected to the battery cells on the first end portion side of the plurality of battery cells, and
the second voltage detection pattern provided on the second extended portions is connected to the battery cells on the second end portion side of the plurality of battery cells.

7. The battery sensing unit according to claim 3,
wherein the first flexible printed circuit includes a second connector mounting portion on which the second connector is mounted, and
the first connector mounting portion and the second connector mounting portion are joined to each other via the first extended portion.

8. The battery sensing unit according to claim 2,
wherein the circuit board includes a rigid board on which the monitoring circuit is mounted.

9. The battery sensing unit according to claim 8, further comprising:
a third connector that connects the rigid board and the first flexible printed circuit to each other,
wherein the third connector is provided at an end portion on the first end portion side of the rigid board in the arrangement direction.

10. A battery busbar module comprising:
the battery sensing unit according to claim 1;
a plurality of busbars that connect the plurality of battery cells in series; and
a case that houses the plurality of busbars and the battery sensing unit.
